(19) United States
(12) Patent Application Publication
(10) Pub. No.: US 2025/0386437 A1
(43) Pub. Date: Dec. 18, 2025

(54) VEHICLE RADAR DEVICE

(71) Applicant: HL KLEMOVE CORPORATION, Incheon (KR)

(72) Inventor: Sang-Min KIM, Incheon (KR)

(21) Appl. No.: 19/052,992

(22) Filed: Feb. 13, 2025

(30) Foreign Application Priority Data
Jun. 14, 2024 (KR) 10-2024-0077278

(51) Int. Cl. H05K 1/18; G01S 7/02; H01Q 1/42

(52) U.S. Cl. CPC H05K 1/181; G01S 7/027; H01Q 1/42; H05K 2201/1059; H05K 2201/10098; H05K 2201/10598

(57) ABSTRACT

A vehicle radar device according to the disclosure may comprise a housing including a receiving space, a printed circuit board having an antenna and disposed in the receiving space of the housing, a radome coupled to a surface of the housing to seal the receiving space, and at least one coupling member coupled to a surface of the radome and having an end portion fixed to the housing through the printed circuit board.

### CROSS-REFERENCE TO RELATED APPLICATION

This application claims priority from Korean Patent Application No. 10-2024-0077278, filed on June 14, 2024, which is hereby incorporated by reference for all purposes as if fully set forth herein.

### BACKGROUND

### Technical Field

The disclosure relates to a vehicle radar device that is easy to assemble and has enhanced radar performance.

### Description of Related Art

Various devices for driving aids or autonomous driving have recently been developed and commercialized. According to this trend, vehicles may be equipped with radar devices that detect surrounding objects and provide information to assist vehicle driving.

Typically, a radar device may include at least one antenna for transmitting and receiving radar signals. For example, the antenna may be mounted on a printed circuit board, bolted into the housing, and sealed through a radome.

However, this method for fixing the printed circuit board may deteriorate radar performance because it is difficult to maintain the distance between the antenna and the radome at a desired design value due to the accumulated tolerance of the components positioned under the printed circuit board. Further, since additional mass production facilities necessary for the bolting process are required, initial investment costs increase and assembly is cumbersome.

### BRIEF SUMMARY

An object of the disclosure is to provide a vehicle radar device that is easy to assemble, as a coupling member for fixing the position of a printed circuit board is coupled to the housing by a press-fit method.

Another object of the disclosure is to provide a vehicle radar device in which the initial investment cost is reduced by enabling the omission of mass production facilities for the bolting process since the coupling member is coupled to the housing by a press-fit method.

Another object of the disclosure is to provide a vehicle radar device with enhanced performance by forming a coupling member with an elastically deformable material, thereby maintaining the distance between the antenna and the radome at a desired design value regardless of the tolerance of members positioned under the printed circuit board.

To achieve the foregoing objects, a vehicle radar device according to the disclosure may comprise a housing including a receiving space, a printed circuit board having an antenna and disposed in the receiving space of the housing, a radome coupled to a surface of the housing to seal the receiving space, and at least one coupling member provided on a surface of the radome and having an end portion fixed to the housing through the printed circuit board.

The coupling member may be formed of an elastically deformable material.

The coupling member may be formed of silicone or a rubber material.

A hardness of the coupling member may be 60 to 180.

The coupling member may be disposed on each edge portion of the radome.

The coupling member may include a head portion coupled to a surface of the radome, a body portion protruding from a surface of the head portion and disposed between the radome and the printed circuit board, and a fixing portion protruding from a surface of the body portion and fixed to the housing through the printed circuit board.

The head portion may be coupled to the radome by an insert-injection process.

The printed circuit board may have a hole through which the fixing portion passes, and the housing may have a recess to which the fixing portion is inserted.

The fixing portion may be fixed to the recess through the hole by a press-fit method.

The fixing portion may be formed to be larger in diameter than the recess and smaller in diameter than the hole.

A height of the body portion may be formed to be larger than a distance between the printed circuit board and an end portion of the housing.

The coupling member may be elastically deformed when the radome is coupled to the housing.

A plurality of guide protrusions may be provided on a surface of the housing, and a plurality of guide holes to which the guide protrusions are inserted may be provided in the printed circuit board.

A surface of the printed circuit board may be seated in the housing, and another surface of the printed circuit board may be pressed by the coupling member to be fixed in position.

A distance between the antenna and the radome may be 1.0 mm to 6.2 mm.

To achieve the foregoing objects, a vehicle radar device according to the disclosure may comprise a housing including a receiving space, a printed circuit board having an antenna and disposed in the receiving space of the housing, a radome coupled to a surface of the housing to seal the receiving space, and at least one coupling member provided on a surface of the radome and, when coupled to the housing, elastically deformed between the printed circuit board and the radome.

The coupling member may be formed of silicone or a rubber material having a hardness of 60 to 180.

The coupling member may include a head portion coupled to a surface of the radome, a body portion protruding from a surface of the head portion and disposed between the radome and the printed circuit board, and a fixing portion protruding from a surface of the body portion and fixed to the housing through the printed circuit board.

A height of the body portion may be formed to be larger than a distance between the printed circuit board and an end portion of the housing.

A surface of the printed circuit board may be seated in the housing, and another surface of the printed circuit board may be pressed by the coupling member to be fixed in position.

According to the disclosure, it is possible to provide ease to assemble as a coupling member for fixing the position of a printed circuit board is coupled to the housing by a press-fit method.

It is also possible to reduce initial investment costs by enabling the omission of mass production facilities for the bolting process since the coupling member is coupled to the housing by a press-fit method.

It is also possible to enhance performance by forming a coupling member with an elastically deformable material, thereby maintaining the distance between the antenna and the radome at a desired design value regardless of the tolerance of members positioned under the printed circuit board.

### BRIEF DESCRIPTION OF THE SEVERAL VIEWS OF THE DRAWINGS

The above and other objects, features, and advantages of the disclosure will be more clearly understood from the following detailed description, taken in conjunction with the accompanying drawings, in which:

FIG. 1 is a view schematically illustrating a state in which a radar device is installed to a vehicle according to the disclosure;

FIG. 2 is an exploded perspective view illustrating a vehicle radar device according to an embodiment of the disclosure;

FIG. 3 is a perspective view illustrating a state in which the printed circuit board is seated in the receiving space of the housing in FIG. 2;

FIG. 4 is a cross-sectional view illustrating a vehicle radar device according to an embodiment of the disclosure;

FIG. 5 is a perspective view illustrating a coupling member according to an embodiment of the disclosure; and

FIG. 6 is a cross-sectional view schematically illustrating a state in which a coupling member is elastically deformed when a radome is coupled to a housing according to an embodiment of the disclosure.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as "including", "having", "containing", "constituting" "make up of', and "formed of' used herein are generally intended to allow other components to be added unless the terms are used with the term "only". As used herein, singular forms are intended to include plural forms unless the context clearly indicates otherwise.

Terms, such as "first", "second", "A", "B", "(A)", or "(B)" may be used herein to describe elements of the disclosure. Each of these terms is not used to define essence, order, sequence, or number of elements etc., but is used merely to distinguish the corresponding element from other elements.

When it is mentioned that a first element "is connected or coupled to", "contacts or overlaps" etc. a second element, it should be interpreted that, not only can the first element "be directly connected or coupled to" or "directly contact or overlap" the second element, but a third element can also be "interposed" between the first and second elements, or the first and second elements can "be connected or coupled to", "contact or overlap", etc. each other via a fourth element. Here, the second element may be included in at least one of two or more elements that "are connected or coupled to", "contact or overlap", etc. each other.

When time relative terms, such as "after," "subsequent to," "next," "before," and the like, are used to describe processes or operations of elements or configurations, or flows or steps in operating, processing, manufacturing methods, these terms may be used to describe non-consecutive or non-sequential processes or operations unless the term "directly" or "immediately" is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term "may" fully encompasses all the meanings of the term "can".

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Hereinafter, various embodiments of the disclosure are described in detail with reference to the accompanying drawings.

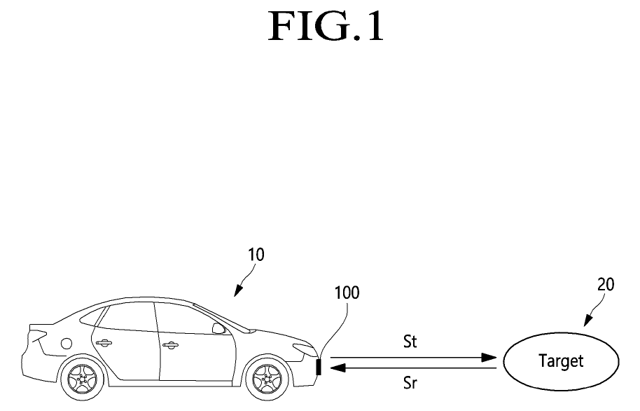

FIG. 1 is a view schematically illustrating a state in which a radar device is installed to a vehicle according to the disclosure.

Referring to FIG. 1, the radar device 100 may be mounted to the vehicle 10 to detect the presence or position of a target 20 in front of the vehicle 10 or to detect a distance from the target 20. In the present embodiment, it is illustrated that the vehicle 10 having the radar device 100 is a passenger car, but is not limited thereto. For example, the radar device 100 is applicable to commercial vehicles, trains, or aircraft.

In the present embodiment, the target 20 to be detected by the radar device 100 may be any object or a specific object nearby. For example, the target 20 may be a vehicle, a person, an object, or the like.

The radar device 100 may emit the transmission signal St in the form of an electromagnetic wave, and receive the reception signal Sr of the emitted transmission signal St hitting the target 20 and returning. Further, based on the received reception signal Sr, it is possible to detect the presence or position of the target 20 or to detect the distance from the target 20.

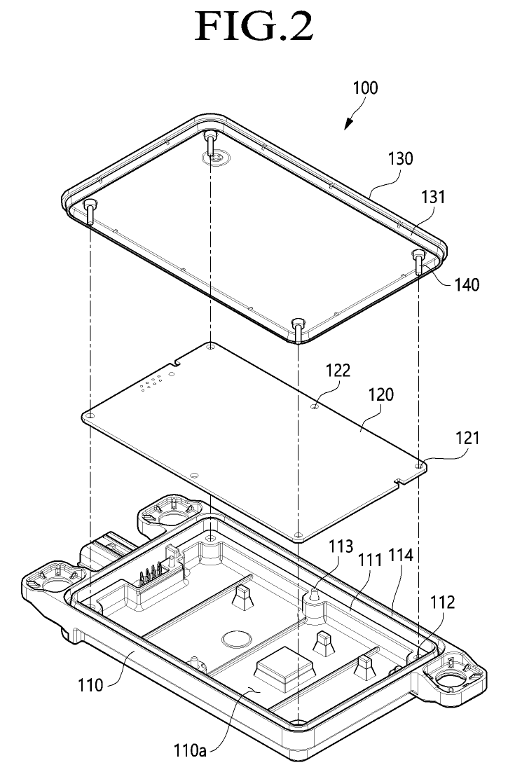

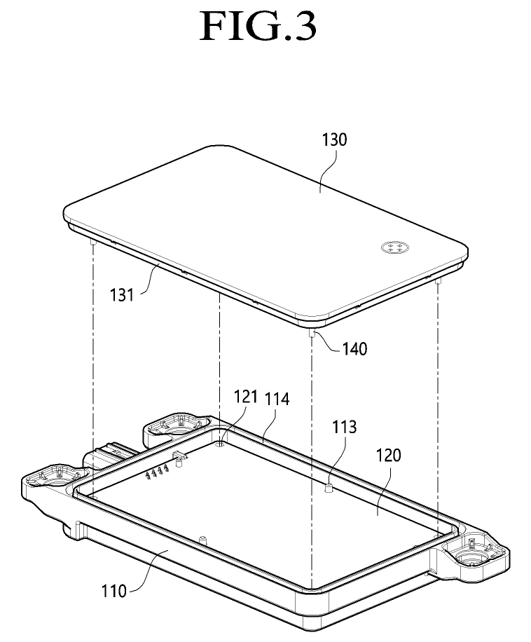

FIG. 2 is an exploded perspective view illustrating a vehicle radar device according to an embodiment of the disclosure. FIG. 3 is a perspective view illustrating a state in which the printed circuit board is seated in the receiving space of the housing in FIG. 2.

Referring to FIGS. 2 to 3, a vehicle radar device 100 may include a housing 110, a printed circuit board 120, a radome 130, and a coupling member 140.

A receiving space 110a for receiving various components may be formed in the housing 110. For example, the housing 110 may be formed in a rectangular box shape with an open top, and a step 111 protruding along the inner circumference of the housing 110 may be formed in the receiving space 110a.

Further, each edge portion of the step 111 may have a recess 112 into which the fixing portion 143 of the coupling member 140 to be described below is inserted, and between the recesses 112, a plurality of guide protrusions 113 for guiding the assembly position of the printed circuit board 120 may be provided.

The printed circuit board 120 may be disposed in the receiving space 110a of the housing 110. For example, the printed circuit board 120 may be seated on the step 111 of the housing 110, and a hole 121 through which the fixing portion 143 of the coupling member 140 passes may be formed at each edge portion.

The position of the printed circuit board 120 may be guided by the guide protrusion 113 provided in the housing 110. For example, the printed circuit board 120 may have a plurality of guide holes 122 in the portions corresponding to the guide protrusions 113, making it easier to determine the seating position of the printed circuit board 120 when the guide hole 122 is inserted into the guide protrusion 113 during assembly.

The numbers of the guide protrusions 113 and the guide holes 122 are not limited, but three or more may be provided to facilitate position guiding.

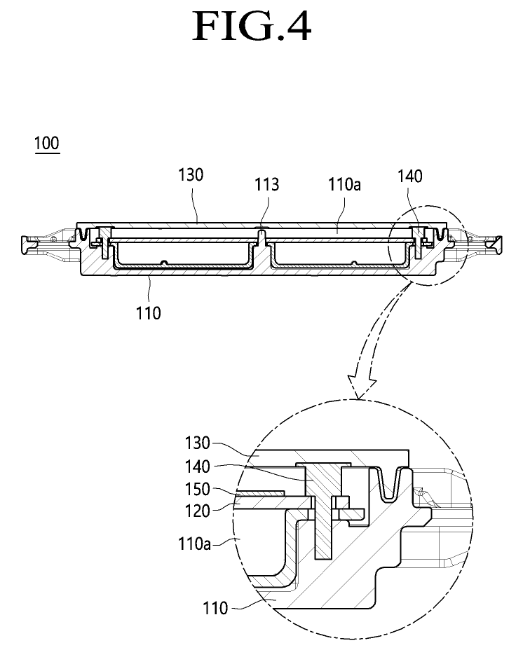

An antenna 150 may be provided on the printed circuit board 120 (see FIG. 4). For example, the antenna 150 may be mounted on the printed circuit board 120. Accordingly, the radar device 100 may recognize the distance between the vehicle 10 and the target 20 and the relative velocity by receiving the reception signal Sr of the transmission signal St transmitted from the antenna 150 and reflected and returned by the target 20.

Although not shown, the printed circuit board 120 may include at least one transmission antenna to radiate the transmission signal St and at least one reception antenna to receive the reception signal Sr.

The antenna 150 may be formed to have various shapes and structures. For example, the antenna 150 may be provided in the form of an array antenna, a microstrip antenna, a patch antenna, etc.

The radome 130 may be coupled to one surface of the housing 110 and may seal the receiving space 110a. For example, the radome 130 may be formed in a rectangular plate shape to seal one open surface of the housing 110. As the receiving space 110a of the housing 110 is sealed by the radome 130, moisture or foreign objects may be prevented from penetrating into the receiving space 110a.

The radar dome 130 may be formed of a material capable of reducing attenuation of transmitted and received radar signals. For example, the radome 130 is formed of a material that allows electromagnetic waves to pass through well, such as plastic, minimizing the loss of electromagnetic waves transmitted and received through the radome 130.

The radome 130 may be coupled to the housing 110 by a press-fit method. To that end, the housing 110 may have a coupling recess portion 114 in the upper edge, and the radome 130 may have a protrusion 131 having a shape corresponding to the coupling recess 114 at the lower portion. Accordingly, when the protrusion 131 is fitted into the coupling recess 114, the radome 130 may be stably coupled to the housing 110.

In the present embodiment, it has been described that the radome 130 is coupled to the housing 110 by a press-fit method, but the disclosure is not limited thereto. For example, the radome 130 and the housing 110 may be coupled by a method such as bolting, bonding, or the like.

The coupling member 140 and the radome 130 may be formed of a single body. For example, the coupling member 140 may be coupled to one surface of the radome 130 and, when the radome 130 is coupled to the housing 110, press an upper portion of the printed circuit board 120 seated on the step 111.

Accordingly, one surface of the printed circuit board 120 may be seated in the housing 110, and the other surface may be pressed by the coupling member 140 to be fixed in position.

At least one coupling member 140 may be provided, and one end portion thereof may pass through the printed circuit board 120 and be fixed to the housing 110. For example, four coupling members 140 may be provided and disposed at each edge of the radome 130. In the present embodiment, it is illustrated that four coupling members 140 are provided, but four or more or four or less coupling members may be provided.

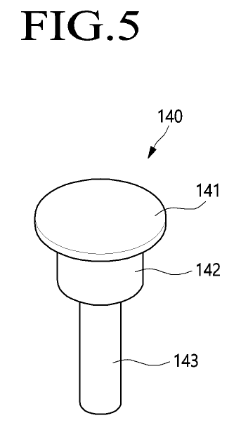

FIG. 4 is a cross-sectional view illustrating a vehicle radar device according to an embodiment of the disclosure. FIG. 5is a perspective view illustrating a coupling member according to an embodiment of the disclosure.

Referring to FIGS. 4 to 5, the coupling member 140 may include a head portion 141, a body portion 142, and a fixing portion 143.

The head portion 141 may be formed in a circular plate shape, and may be coupled to one surface of the radome 130. For example, the head portion 141 may be coupled to the radome 130 by an insert injection process.

In the present embodiment, it has been described that the head portion 141 is coupled to the radome 130 by an insert injection process, but may be coupled to the radome 130 through a method such as bolting or bonding.

The body portion 142 may protrude from one surface of the head portion 141, and may be disposed between the radome 130 and the printed circuit board 120. Accordingly, when the radome 130 is coupled to the housing 110, the body portion 142 presses the printed circuit board 120, thereby preventing the printed circuit board 120 from escaping off the housing 110.

In this case, by forming the height of the body portion 142 to be larger than the distance between the printed circuit board 120 and an end portion of the housing 110, it is possible to stably press the printed circuit board 120 when the body portion 142 is disposed between the radome 130 and the printed circuit board 120. For example, the height of the body portion 142 may be larger than the distance between the printed circuit board 120 and the end portion of the housing 110 by 0.5 mm to 2.5 mm.

The fixing portion 143 may protrude from one surface of the body portion 142, and may be coupled to the housing 110 through the printed circuit board 120. For example, the fixing portion 143 may pass through the hole 121 of the printed circuit board 120 and be press-fitted into the recess 112 formed in the step 111 of the housing 110. To that end, the diameter of the fixing portion 143 may be larger than the diameter of the recess 112 and smaller than the diameter of the hole 121.

As the coupling member 140 for fixing the position of the printed circuit board 120 is fixed to the housing 110 by a press-fit method, assembly may be easy.

In other words, since the conventional coupling member is bolted to the housing 110, assembly is cumbersome because a fastening member such as a bolt should be prepared separately and then tightened, and the initial investment cost may be increased because additional mass production facilities necessary for the bolting process are required. In contrast, according to the disclosure, as the coupling member 140 is fixed to the housing 110 by a press-fit method, assembly may be easy, and no mass production facilities are required, saving initial investment costs.

Meanwhile, the performance of the antenna 150 may be secured only when the distance h between the radome 130 and the antenna 150 is maintained at a preset design value. In the present embodiment, the distance h between the antenna 150 and the radome 130 may be 1.0 mm to 6.2 mm, more specifically 3.8 mm to 4.2 mm.

In other words, if the distance between the antenna 150 and the radome 130 is less than 1.0 mm or exceeds 6.2 mm, the performance of the antenna 150 may be deteriorated, and the best performance may be implemented when it is 3.8 mm to 4.2 mm.

As such, since there is no performance deterioration when the distance h between the antenna 150 and the radome 130 meets a preset design value, it is critical to provide a constant distance h between the antenna 150 and the radome 130 as an initial design value when manufacturing the radar device 100.

To that end, in the present embodiment, the coupling member 140 may be integrally provided with the radome 130 and then formed of an elastically deformable material. The coupling member 140 may be formed of at least one material selected from the group consisting of natural rubber (NR), nitrile butadiene rubber (NBR), chloroprene rubber (CR), ethylene propylene terpolymer (EPDM), fluoro rubber (FPM), styrene butadiene rubber (SBR), chlorosulfonated polyethylene (CSM), urethane and silicone to provide weatherproofness and elasticity.

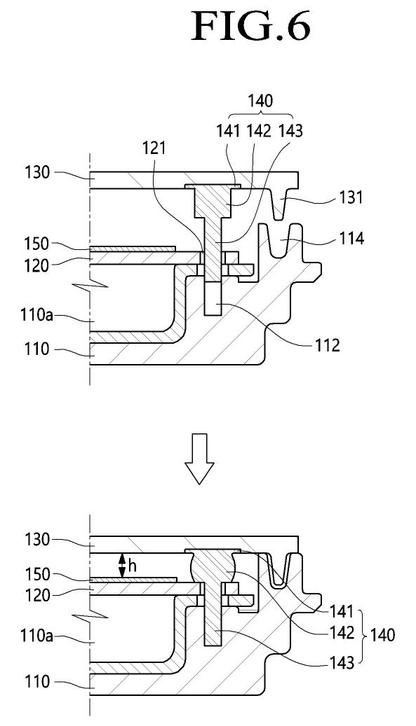

Hereinafter, a method for constantly providing the distance h between the antenna 150 and the radome 130 to a preset design value is described in detail with reference to FIG. 6.

FIG. 6 is a cross-sectional view schematically illustrating a state in which a coupling member is elastically deformed when a radome is coupled to a housing according to an embodiment of the disclosure.

Referring to FIG. 6, the coupling member 140 fixed to the radome 130 may be formed of an elastically deformable material. For example, the coupling member 140 may be formed of silicone or a rubber material having a hardness of 60 to 180 international rubber hardness degree (IRHD) (hereinafter, the unit is omitted). This is because when the hardness of the coupling member 140 is less than 60, the support force may be weakened, and when it exceeds 180, elastic deformation may be difficult. More specifically, the hardness of the coupling member 140 may be provided in the range of 100 to 150.

As the coupling member 140 is formed of a high-hardness and elastically deformable material, it is possible to maintain the distance h between the antenna 150 and the radome 130 at a desired design value while stably fixing it in the housing 110.

In other words, when the radome 130 is coupled to the housing 110, the body portion 142 disposed between the printed circuit board 120 and the radome 130 is elastically deformed and compressed, so that the distance h between the antenna 150 and the radome 130 may be kept constant at the desired design value regardless of the tolerance of the members positioned under the printed circuit board 120. Accordingly, the performance of the vehicle radar device 100 may be maintained to the maximum.

As described above, the vehicle radar device 100 according to the disclosure has the advantage of being easy to assemble as the coupling member 140 for fixing the printed circuit board 120 in the housing 110 is coupled to the housing 110 by a press-fit method.

Further, as the coupling member 140 is coupled to the housing 110 in a press-fit method, mass production facilities for the bolting process may be omitted, saving initial investment costs.

Further, there may be provided a vehicle radar device 100 with enhanced performance by forming a coupling member 140 with an elastically deformable material, thereby maintaining the distance between the antenna 150 and the radome 130 at a desired design value regardless of the tolerance of members positioned under the printed circuit board.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure. Thus, the scope of the disclosure is not limited to the embodiments shown, but is to be accorded the widest scope consistent with the claims. The scope of the disclosure should be construed by the following claims, and all technical spirits within equivalents thereof should be interpreted to belong to the scope of the disclosure.

1. A vehicle radar device, comprising:
a housing including a receiving space;
a printed circuit board having an antenna and disposed in the receiving space of the housing;
a radome coupled to a surface of the housing to seal the receiving space; and
at least one coupling member provided on a surface of the radome and having an end portion fixed to the housing through the printed circuit board.

2. The vehicle radar device of claim 1, wherein the coupling member is formed of an elastically deformable material.

3. The vehicle radar device of claim 1, wherein the coupling member is formed of silicone, urethane or a rubber material.

4. The vehicle radar device of claim 1, wherein a hardness of the coupling member is 60 to 180.

5. The vehicle radar device of claim 1, wherein the coupling member is disposed on each edge portion of the radome.

6. The vehicle radar device of claim 1, wherein the coupling member includes:
a head portion coupled to a surface of the radome;
a body portion protruding from a surface of the head portion and disposed between the radome and the printed circuit board; and
a fixing portion protruding from a surface of the body portion and fixed to the housing through the printed circuit board.

7. The vehicle radar device of claim 6, wherein the head portion is coupled to the radome by an insert-injection process.

8. The vehicle radar device of claim 6, wherein the printed circuit board has a hole through which the fixing portion passes, and the housing has a recess to which the fixing portion is inserted.

9. The vehicle radar device of claim 8, wherein the fixing portion is fixed to the recess through the hole by a press-fit method.

10. The vehicle radar device of claim 8, wherein the fixing portion is formed to be larger in diameter than the recess and smaller in diameter than the hole.

11. The vehicle radar device of claim 6, wherein a height of the body portion is formed to be larger than a distance between the printed circuit board and an end portion of the housing.

12. The vehicle radar device of claim 1, wherein the coupling member is elastically deformed when the radome is coupled to the housing.

13. The vehicle radar device of claim 1, wherein a plurality of guide protrusions are provided on a surface of the housing, and a plurality of guide holes to which the guide protrusions are inserted are provided in the printed circuit board.

14. The vehicle radar device of claim 1, wherein a surface of the printed circuit board is seated in the housing, and another surface of the printed circuit board is pressed by the coupling member to be fixed in position.

15. The vehicle radar device of claim 1, wherein a distance between the antenna and the radome is 1.0 mm to 6.2 mm.

16. A vehicle radar device, comprising:
a housing including a receiving space;
a printed circuit board having an antenna and disposed in the receiving space of the housing;
a radome coupled to a surface of the housing to seal the receiving space; and
at least one coupling member provided on a surface of the radome and, when coupled to the housing, elastically deformed between the printed circuit board and the radome.

17. The vehicle radar device of claim 16, wherein the coupling member is formed of silicone, urethane or a rubber material having a hardness of 60 to 180.

18. The vehicle radar device of claim 16, wherein the coupling member includes:
a head portion coupled to a surface of the radome;
a body portion protruding from a surface of the head portion and disposed between the radome and the printed circuit board; and
a fixing portion protruding from a surface of the body portion and fixed to the housing through the printed circuit board.

19. The vehicle radar device of claim 18, wherein a height of the body portion is formed to be larger than a distance between the printed circuit board and an end portion of the housing.

20. The vehicle radar device of claim 16, wherein a surface of the printed circuit board is seated in the housing, and another surface of the printed circuit board is pressed by the coupling member to be fixed in position.
